(19) United States
(12) Patent Application Publication
(10) Pub. No.: US 2026/0282960 A1
(43) Pub. Date: Sep. 17, 2026

(54) INTEGRATED CIRCUITY DEVICE WITH FLEXIBLE ROUTING AT HYBRID BONDING LAYER

(71) Applicant: Advanced Micro Devices, Inc., Santa Clara, CA (US)

(72) Inventors: Hsiang-Wei LIU, Zhubei City (TW); Liwei WANG, Austin, TX (US)

(21) Appl. No.: 19/079,308

(22) Filed: Mar. 13, 2025

(51) Int. Cl. H01L 23/538; H01L 21/768; H01L 25/18

(52) U.S. Cl. CPC H10W 70/65; H10W 20/056; H10W 20/076; H10W 70/611; H10W 70/635; H10W 90/00

(57) ABSTRACT

Disclosed herein are integrated circuit (IC) dies, and electronic devices including the same, that include flexible routing arrangements at a hybrid bonding layer featuring an etch stop layer. The etch stop layer enables vias connected with the hybrid bonding layer to terminate at both contact pads formed on the surface of the IC die and buried conductive pads formed on a top metal layer of the IC die.

### TECHNICAL FIELD

Embodiments of the present disclosure generally relate to integrated circuit die, and electronic devices including the same, that include flexible routing arrangements at the hybrid bonding layer featuring an etch stop layer.

### BACKGROUND

High speed signaling is fundamental to all data center and AI/ML applications today. Reliable coherent chip to chip communication and low-latency memory access is essential for scale up/scale out of generative AI, as well as the mainstream modular datacenter (MDC) server markets. Interfaces utilized for high speed signaling require sufficient space to both contact pads and routing. As contact pad density increases, routing becomes more and more complex, as increases in routing density can often make the interface susceptible to undesirable crosstalk and noise. Thus, the design layouts for high-speed interfaces not only require additional silicon space, but also undesirably have a more time consuming design processes and undesirably add to the cost of manufacturing.

In next generation System on Integrated Chip (SoIC) packages, coupling integrated circuit (IC) dies using hybrid bonding techniques is becoming more popular. Hybrid bonding uses bond pad metal surrounded by a dielectric material. The dielectric material of the facing IC dies create a non-metal to non-metal bond using fusion bonding of the dielectric material, while metal-to-metal bonds are formed across the bond pad metal of the adjacent IC dies. In current technology, bond pad vias coupled to the bond pad metal can only can land on common single layer within the IC die due to etching process loading effects. For example, bond pad vias can only landing on either exposed bond pad or on last copper metal layer buried within the IC die. As the bond pad vias are constrained to land only at a common level, routing design flexibility is consequentially constrained as well.

Thus, there is a need for an improved hybrid bonding interface that enables more flexible routing arrangements than currently available.

### SUMMARY

Disclosed herein are integrated circuit (IC) dies, and electronic devices including the same, that include flexible routing arrangements at a hybrid bonding layer featuring an etch stop layer. The etch stop layer enables vias connected with the hybrid bonding layer to terminate at both contact pads formed on the surface of the IC die and buried conductive pads formed on a top metal layer of the IC die.

In one example, an integrated circuit (IC) die is provided. The IC die includes a substrate, a front end of the line (FEOL) region, a back end of the line (BEOL) region, an etch stop layer, and a hybrid bonding layer. The FEOL region is disposed on the substrate and includes functional circuitry. The BEOL region has a first side disposed on the FEOL region and a second side facing away from the FEOL region. The BEOL region includes interconnect circuitry coupled to the functional circuitry. The interconnect circuitry includes a top metal layer disposed adjacent to the second side of the BEOL region and a contact pad coupled to the top metal layer by a contact pad via. The etch stop layer is disposed on the second side of the BEOL region. The hybrid bonding layer is disposed on the etch stop layer. The hybrid bonding layer includes a first metal filled via contacting the top metal layer though a first opening formed in the etch stop layer and a second metal filled via contacting the contact pad though a second opening formed in the etch stop layer.

In another example, an IC device is provided. The IC device includes a first IC die stacked with a second IC die. The first IC die has a first hybrid bonding layer disposed on a first etch stop layer of the first IC die. The first hybrid bonding layer include a first metal filled via contacting a top metal layer of the first IC die though a first opening formed in the first etch stop layer, and a second metal filled via contacting a contact pad of the first IC die though a second opening formed in the first etch stop layer. The contact pad is coupled to first metal layer by a contact pad via. The second IC die has a second hybrid bonding layer hybrid bonded to the first hybrid bonding layer.

In another example, a method for forming an integrated circuity die is provided. The method includes depositing an etch stop layer over a contact pad exposed on an IC die, the contact pad coupled by a via to a first metal layer of the IC die; forming a first opening in the etch stop layer; depositing an insulative material over the etch stop layer; forming a first via through the insulative material, the first via stopping on the etch stop layer; forming a second via through the insulative material and through the first opening of the etch stop layer, the second via stopping on the first metal layer; forming a second opening in the etch stop layer that exposes a portion of the contact pad; and filling the first and second vias with conductive material.

In yet another example, a method for stacking IC dies is provided. The method includes forming non-metal to non-metal bonds between a first hybrid bonding layer of a first IC die and a second hybrid bonding layer of a second IC die; and forming metal-to-metal bonds between hybrid bond pads of the first and second hybrid bonding layers of the first and second IC dies. A first one of the hybrid bond pads of the first hybrid bonding layer is coupled by a first metal filled via of the first hybrid bonding layer to a top metal layer of the first IC die though a first opening formed in an first etch stop layer. A second one of the hybrid bond pads of the first hybrid bonding layer is coupled by a second metal filled via of the first hybrid bonding layer to contact pad disposed between top metal layer and the first etch stop layer through a first opening formed in the first etch stop layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1J are partial sectional schematic views of an integrated circuit (IC) die during different stages of fabrication.

FIG. 2 is a flow diagram of a method of fabricating an IC die, stages of which are illustrated in FIGS. 1A-1J.

FIGS. 3A-3B are partial sectional schematic views of die stack and chip package having a die stack.

FIG. 4 is a flow diagram of a method of fabricating a chip package, stages of which are illustrated in FIGS. 3A-3B.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure generally provide integrated circuit (IC) dies, and electronic devices including the same, that include flexible routing arrangements at a hybrid bonding. The routing flexibility is enabled by the presence of an etch stop layer disposed between the hybrid bonding layers and the contact pads of the IC die. The etch stop layer enables vias connected with the hybrid bonding layer to terminate at both contact pads formed on the surface of the IC die and buried conductive pads formed on a top metal layer of the IC die. Stated differently, the etch stop layer is utilized to allow vias to terminate on different metal layers of the IC die using a single via forming process. The etch stop layer has an opening aligned with the buried conductive pads while covering the contact pads. When the vias are formed over the buried conductive pads and contact pads, the etch stop layer protects the contact pads exposed by some vias, while enabling other vias formed over the buried conductive pads to be efficiently etch deeper until contacting the buried conductive pads. The etch stop layer over the contact pads is then opened to allow conductive material to fill the vias over both the buried conductive pads and contact pads. The ability to form vias that terminate at both the buried conductive pads and surface level contact pads enables routing congestion to be alleviated, enabling greater architectural and design flexibility, along with greater routing density.

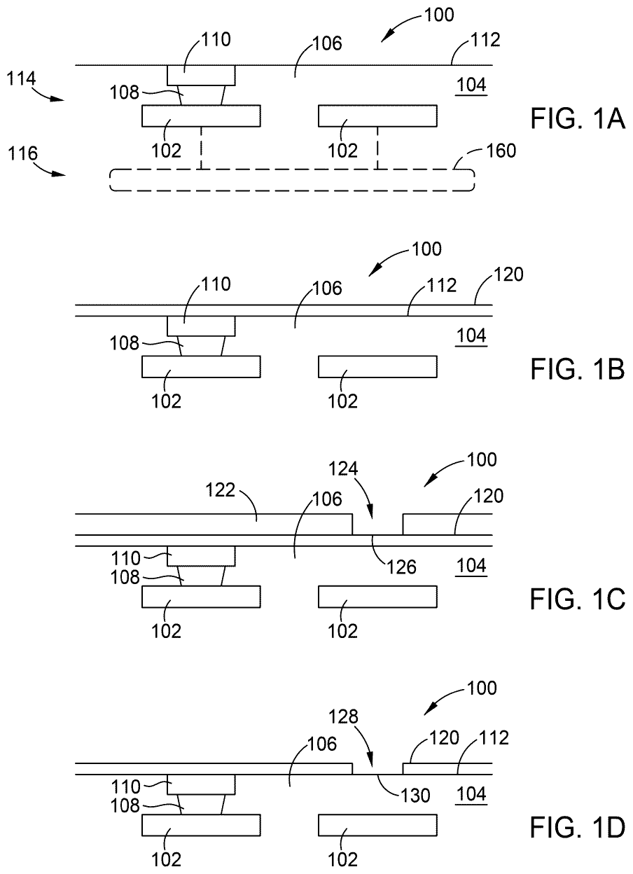

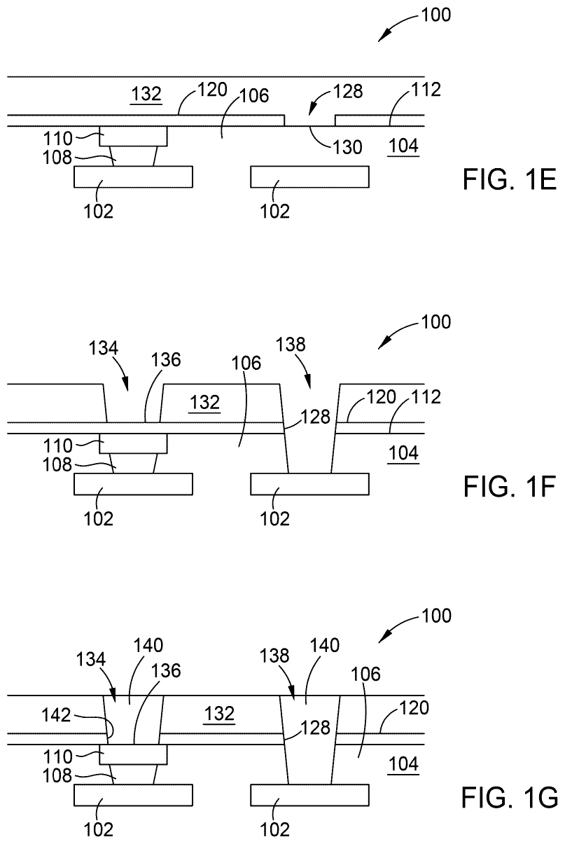

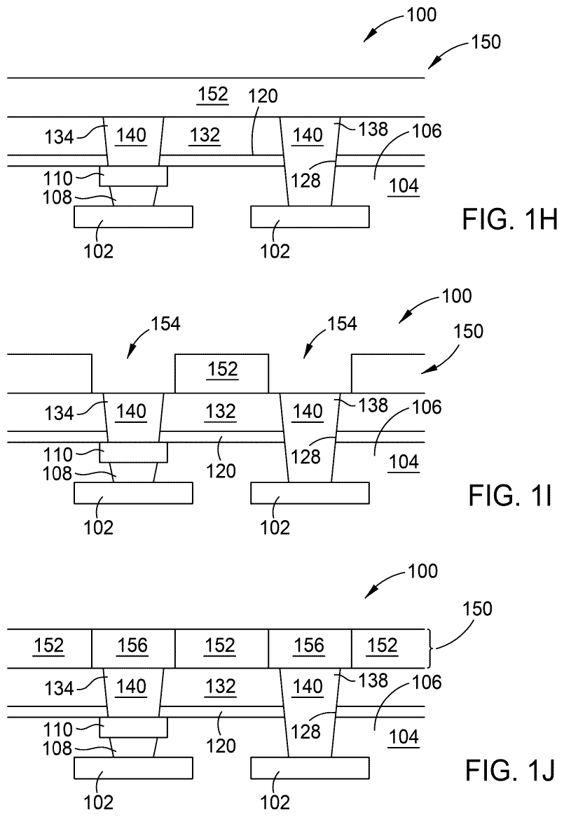

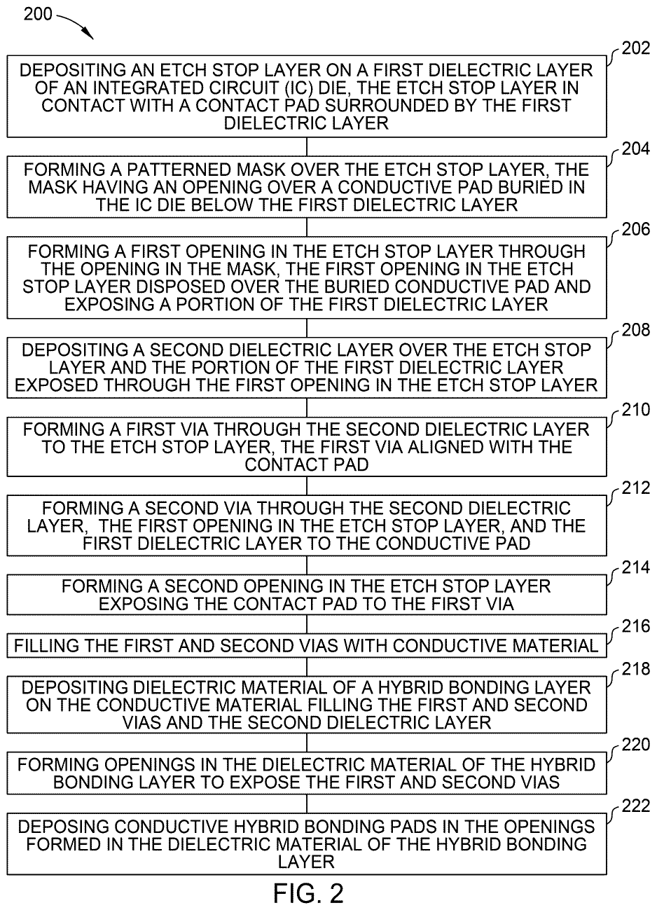

Turning now to FIGS. 1A-1J, partial sectional schematic views of an integrated circuit (IC) die 100 are illustrated during different stages of fabrication. The stages of fabrication correspond to a method 200 of fabricating an IC die, the flow diagram of which is illustrated in FIG. 2. As first illustrated in FIG. 1A, the IC die 100 includes a back end of the line (BEOL) region 114, and a front end of the line (FEOL) region 116. The BEOL region 114 includes conductive pads 102 buried in BEOL dielectric material 104 and contact pads 110 exposed on a top surface 112 of the IC die 100. The BEOL region 114 is formed on the FEOL region 116. The FEOL region 116 functional circuitry 160 of the IC die 100. The functional circuitry 160 disposed in the FEOL region 116 is connected by routing to the contact pads 110 and the conductive pads 102 disposed in the BEOL region 114. Although only one contact pad 110 and two conductive pads 102 are shown in FIG. 1A, it is to be understood that the IC die 100 includes many contact pads 110 and many conductive pads 102.

The BEOL dielectric material 104 is formed from multiple layers of dielectric material that insulate the lines and via forming the interconnect routing in the BEOL region of the IC die 100 that couples the functional circuitry 160 to the conductive pads 102 and contact pads 110. The BEOL dielectric material 104 includes a top dielectric layer 106 that form a top surface 112 of the IC die 100. The BEOL dielectric material 104 may be a low-k dielectric material, oxide, nitride or other dielectric material suitable for use as a pre-metal dielectric (PMD) or an interlevel dielectric (“ILD”). Other suitable BEOL dielectric materials includes SiNₓ, SiCyNₓ, SiO_{y}Nₓ, and TiOₓ, where X and Y are positive numbers.

The contact pads 110 are exposed on the top surface 112 of the IC die 100. The contact pads 110 are laterally surrounded and isolated from one another by the top dielectric layer 106 and/or other dielectric layers comprising BEOL dielectric material 104. The contact pads 110 may be fabricated from copper or other suitable conductive material.

The contact pads 110 are coupled to the conductive pads 102 by vias 108. The vias 108 are formed from copper or other suitable conductive material.

The conductive pads 102 are formed from the top metal layer of the BEOL region of the IC die 100 closest to the top surface 112. Thus, the conductive pads 102 are buried in the BEOL material 104 and spaced below the top surface 112 of the IC die 100. The conductive pads 102 are formed from copper or other suitable conductive material. As stated briefly above, the conductive pads 102 are coupled to the functional circuitry 160 of the IC die 100 that resides in the FEOL region 116. The functional circuitry 160 of the IC die 100 may include memory circuitry, logic (processing) circuitry, and/or photonic integrated circuitry, among other types of circuitry.

In one example, the functional circuitry 160 of the IC die 100 includes one or more central processing unit (CPU) cores. As such, the IC die 100 containing CPU cores may be referred to as a CPU die or CPU chiplet. The functional circuitry 160 of the IC die 100 may also include System Management Unit (SMU). The SMU is circuitry configured to monitor thermal and power conditions and adjust power and cooling to keep the dies 100 functioning as within specifications. The functional circuitry 160 of the IC die 100 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry 160 of the IC die 100 includes accelerated compute cores. As such, the IC die 100 containing accelerated compute cores may be referred to as an accelerator die or accelerator chiplet. The IC die 100 containing accelerated compute cores may also be referred to as a graphic processing unit (GPU) die or GPU chiplet. The accelerated compute cores contained in the functional circuitry 160 of the IC die 100 generally includes math engine circuitry. The math engine circuitry is generally designed for task specific computing, such as used data center computing, high performance computing and AI/ML computing. Along with the accelerated compute cores, functional circuitry 160 of the IC die 100 may also include SMU circuitry and DFX circuitry.

In another example, the functional circuitry 160 of the IC die 100 includes memory circuitry. Examples of memory circuitry includes dynamic random-access memory (DRAM), ferroelectric random-access memory (FeRAM), and magneto resistive random-access memory (MRAM), among other types of memory circuitry. As such, the IC die 100 containing memory circuitry may be referred to as a memory die or memory chiplet.

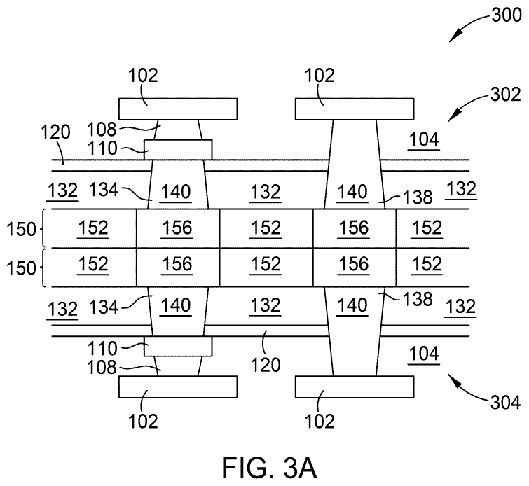

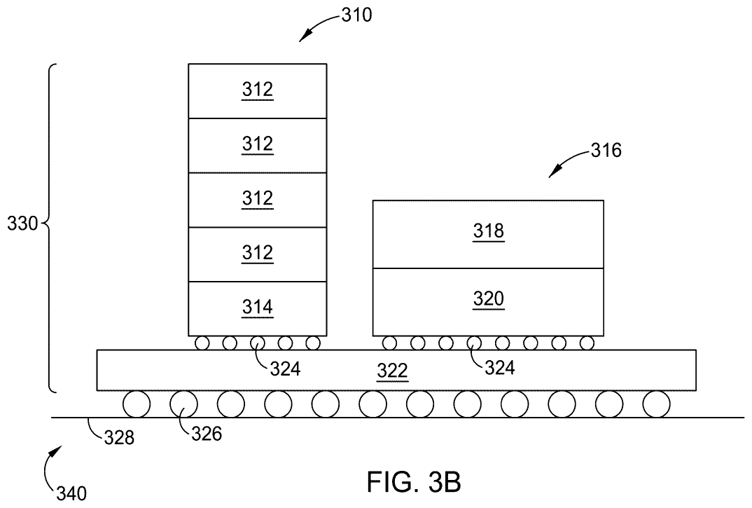

In other examples, the functional circuitry 160 the IC die 100 may be the same or different than another IC die 100 then two or more IC dies 100 are stacked together, as later discussed below (with reference to a die stack 300 illustrated in FIG. 3A). In one example, one IC die 100 may include accelerated compute cores, while another IC die 100 includes CPU cores. In other examples, one IC die 100 may include CPU and/or accelerated compute cores, while another IC die 100 may be one of a stack of memory dies containing memory circuitry, such as to form a high bandwidth memory (HBM) device.

Referring now to FIGS. 1A-1J and FIG. 2, the method 200 begins at operation 202 by depositing an etch stop layer 120 on the top dielectric layer 106 of the IC die 100, as illustrated in FIG. 1B. The etch stop layer 120 is in direct contact with the contact pad 110 that is surrounded by the top dielectric layer 106. The etch stop layer 120 also overlays with the conductive pad 102 that is buried in BEOL dielectric material 104. The etch stop layer 120 may be deposited by any suitable technique, such as by not limited to chemical vapor deposition. The etch stop layer 120 may have a thickness of between about 0.5 μm to about 20.0 μm. The etch stop layer 120 may comprise one or more layers of material, with at least one layer fabricated from an insulative material that has high etching selectivity to an insulative material bounding the vias in the first hybrid bonding layer (as later discussed below). In one example, the etch stop layer 120 includes at least one layer fabricated from a material that can be etch selectively relative to BEOL materials. Some examples of materials suitable for fabricating the first etch stop layer 120 include silicon nitride (SiN), aluminum oxide (AlOx), aluminum nitride (AlN), and silicon carbonitride (SiCN), among others.

At operation 204, a patterned mask 122 is formed over the etch stop layer 120, as illustrated in FIG. 1C. The patterned mask 122 has an opening 124 over 126 formed over the conductive pad 102 buried in the IC die 100 below the top dielectric layer 106. The opening 124 in the patterned mask 122 exposes a portion 126 of the etch stop layer 120. The patterned mask 122 may be formed by any suitable technique. In one example, the patterned mask 122 is formed by applying a photoresist material on the etch stop layer 120, exposing the photoresist material through a reticle to transfer a pattern to the photoresist material, and removing the unexposed photoresist material to form the opening 124 in the patterned mask 122.

At operation 206, an opening 128 in the etch stop layer 120 is formed through the opening 124 in the patterned mask 122. The patterned mask 122 may be remove while forming the opening 128 in the etch stop layer 120, or removed, for example by ashing, after the opening 128 is formed in the etch stop layer 120, as illustrated in FIG. 1D. The opening 128 in the etch stop layer 120 is formed over the buried conductive pad 102, and exposes a portion 130 of the top dielectric layer 106. The opening 128 in the etch stop layer 120 may be formed by wet or dry etching. In one example, the opening 128 in the etch stop layer 120 is formed by plasma etching the etch stop layer 120 using a gas mixture comprising CF₄, CHF₃, and O₂. In another example, the opening 128 in the etch stop layer 120 is formed by wet etching the etch stop layer 120 using an HF solution. The opening 128 in the etch stop layer 120 may be formed using other suitable etchants.

At operation 208, a second dielectric layer 132 is deposited over the etch stop layer 120 and the portion 130 of the top dielectric layer 106 exposed through the opening 128 in the etch stop layer 120, as illustrated in FIG. 1E. The second dielectric layer 132 may be spun-on, deposited using flowable chemical vapor deposition, deposited using plasma assisted chemical vapor deposition, or deposited using another suitable technique. In one example, the second dielectric layer 132 is an oxide. In other examples, the second dielectric layer 132 may be fabricated from a material suitable for forming the BEOL dielectric material 104, examples of which have been described above. In some examples, the second dielectric layer 132 and the BEOL dielectric material 104 are fabricated from the same material.

At operation 210, a first via 134 is formed through the second dielectric layer 132 to the etch stop layer 120, as illustrated in FIG. 1F. The first via 134 is aligned with the contact pad 110. The first via 134 exposes a portion 136 of the etch stop layer 120 which is directly above the contact pad 110. The first via 134 may be formed using an etchant elective to the second dielectric layer 132 relative to the etch stop layer 120. In one example, the first via 134 may be plasma etch using fluorine-based gases, such as SF₆, C₄F₈, and the like, mixed with oxygen.

At operation 212, a second via 138 is formed through the second dielectric layer 132, the first opening 128 in the etch stop layer 120, and the BEOL dielectric material 104 (including the top dielectric layer 106) to the conductive pad 102, as also illustrated in FIG. 1F. Operations 210 and 212 may be performed simultaneously, for example in a single etching process, to form the first and second vias 134, 138.

At operation 214, a second opening 142 is formed in the etch stop layer 120 exposing a portion 136 of the contact pad 110 to the first via 134, as illustrated in FIG. 1G. The second opening 142 may be formed using an etchant that is selective to etch stop layer 120 over the second dielectric layer 132 and the metal material of the conductive pad 102.

At operation 216, the first and second vias 134, 138 are filled with conductive material 140, as also illustrated in FIG. 1G. The conductive material 140 may be copper or other suitable conductor. The conductive material 140 may include a copper seed layer disposed under bulk deposited copper. The copper seed layer, when present, may have a thickness of between about 0.5 μm to about 5.0 μm.

A barrier layer (not shown) may be disposed between the sidewalls of first and second vias 134, 138 and the conductive material 140. The barrier layer may be formed from Ti, TiN, Ni, TaN or other suitable barrier material. The barrier layer may be deposited via a physical vapor deposition process, or other suitable technique.

At operation 218, a dielectric material 152 of a hybrid bonding layer 150 is deposed on the conductive material 140 filling the first and second vias 134, 138 and the second dielectric layer 132, as illustrated in FIG. 1H. The dielectric material 152 of the hybrid bonding layer 150 may be formed from oxides, thermal oxides, SiO₂, SiN, SiCN, polybenzoxazole (PBO), polyimide (PI), benzocyclobutene (BCB), among others. The dielectric material 152 allows the IC die 100 to initially bond, for example by fusion bonding, to the exposed top surface of another of IC die, as later described herein.

At operation 220, openings 154 are formed in the dielectric material 152, as illustrated in FIG. 1I. The openings 154 may be formed by masking and patterning, or other suitable technique. The openings 154 in the dielectric material 152 expose the tops of the conductive material 140 filling the first and second vias 134, 138.

At operation 222, conductive hybrid bonding pads 156 are formed in the openings 154 of the dielectric material 152 of the hybrid bonding layer 150, as illustrated in FIG. 1J. The conductive hybrid bonding pads 156 are formed from copper or other suitable conductive material. In one example, the conductive hybrid bonding pads 156 are plated on the exposed the tops of the conductive material 140 filling the first and second vias 134, 138. The conductive hybrid bonding pads 156 allows the IC die 100 to form metal-to-metal bonds between the conductive hybrid bonding pads exposed on the top surface of another IC die. The conductive hybrid bonding pads 156, exposed to pressure and heat, form eutectic metal bonds with the conductive hybrid bonding pads the other IC die being stacked therewith, as further described below.

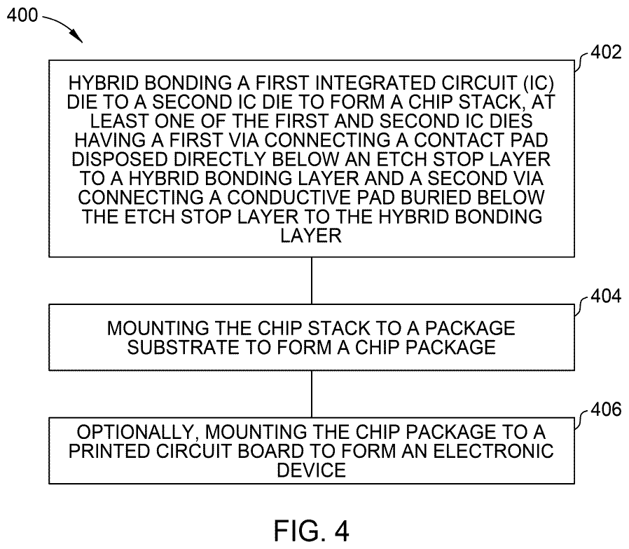

FIGS. 3A-3B are partial sectional schematic views of die stack 300 and chip package 330 having at least one die stack 300. FIG. 4 is a flow diagram of a method 400 of fabricating a chip package 330, stages of which are illustrated in FIGS. 3A-3B.

The method 400 begins at operation 402 by hybrid bonding a first integrated circuit (IC) die 302 to a second IC die 304 to form a die stack 300, as illustrated in FIG. 3A. Although the die stack 300 includes only two IC dies 302, 304, the die stack 300 may alternatively include more than two IC dies. The IC dies 302, 304 of the die stack 300 are configured as described above with reference to the IC die 100, and may be of the same type, be of different types, or a mix of same and different types. In one example, at least two of the IC dies 302, 304 of the die stack 300 are configured as memory dies. Two or more of the memory dies 302, 304 of a die stack 300 may also be stacked with another IC die 100 configured as a buffer or logic die. One or more of the IC dies 302, 304 of the die stack 300 may also include functional circuitry having one or more accelerated compute cores and/or one or more central processing unit (CPU) cores.

In the hybrid bonded die stack 300, at least one of the first and second IC dies 302, 304 has a first via 134 connecting a contact pad 110 disposed directly below an etch stop layer 120 to a hybrid bonding layer 150 and a second via 138 connecting a conductive pad 102 buried below the etch stop layer 120 to the hybrid bonding layer 150.

Operation 402 is generally performed forming non-metal to non-metal bonds using fusion bonding of the hybrid bonding dielectric layer 152, and forming metal-to-metal bonds across the hybrid bonding pads 156 of the adjacent IC dies 302, 304. The metal-to-metal bonds may be formed using pressure and heat to form eutectic metal bonds.

In one example, operation 402 may be performed by forming non-metal to non-metal bonds between a first hybrid bonding layer of a first IC die and a second hybrid bonding layer of a second IC die, the forming metal-to-metal bonds between hybrid bond pads of the first and second hybrid bonding layers of the first and second IC dies. A first one of the hybrid bond pads of the first hybrid bonding layer is coupled by a first metal filled via of the first hybrid bonding layer to a top metal layer of the first IC die though a first opening formed in an first etch stop layer. A second one of the hybrid bond pads of the first hybrid bonding layer is coupled by a second metal filled via of the first hybrid bonding layer to contact pad disposed between top metal layer and the first etch stop layer a first opening formed in the first etch stop layer.

At operation 404, the die stack is mounted to a package substrate 322 to form a chip package 330, as illustrated in FIG. 3B. The chip package 330 may have one or more die stacks. In the chip package 330 illustrated in FIG. 3B, the chip package 330 includes a first die stack 310 and a second die stack 316. At least one or both of the die stacks 310, 316 include hybrid bonded IC dies 302, 304 such as illustrated in the die stack 300. The die stacks 310, 316 may be mounted to the package substrate 322 using solder interconnects 324, such as solder bumps.

In the example depicted in FIG. 3B, the chip package 330 is configured as a high bandwidth memory (HBM) device. The first die stack 310 of the chip package 330 includes a plurality of memory IC dies 312, any two of which may be configured as shown in the die stack 300. The first die stack 310 may also include a buffer IC die 314 which include memory controller circuity. The second die stack 316 of the chip package 330 includes a plurality of compute dies, shown as compute die 318 and compute die 320. The second die stack 316 of the chip package 330 may also include other IC dies. The compute dies 318, 320 may be configured as shown in the die stack 300.

Optionally at operation 406, the chip package 330 may be mounted to a printed circuit board 328 to form an electronic device 340, as also illustrated in FIG. 3B. The chip package 330 may be mounted to the printed circuit board 328 using solder balls 326 or a socket.

The above described technology may be expressed in one or more of the following non-limiting examples.

Example 1. An integrated circuit (IC) die including a substrate; a front end of the line (FEOL) region disposed on the substrate, the FEOL region including functional circuitry; a back end of the line (BEOL) region having a first side disposed on the FEOL region and a second side facing away from the FEOL region, the BEOL region including interconnect circuitry coupled to the functional circuitry, the interconnect circuitry including a top metal layer disposed adjacent to the second side of the BEOL region and a contact pad coupled to the top metal layer by a contact pad via; an etch stop layer disposed on the second side of the BEOL region; and a hybrid bonding layer disposed on the etch stop layer, the hybrid bonding layer including: a first metal filled via contacting the top metal layer though a first opening formed in the etch stop layer; and a second metal filled via contacting the contact pad though a second opening formed in the etch stop layer.

Example 2. The IC die of Example 1, wherein the BEOL region includes at least one layer fabricated from a material selected from the group consisting of SiNₓ, SiCyNₓ, SiO_{y}Nₓ, and TiOₓ, where X and Y are positive numbers.

Example 3. The IC die of Example 1, wherein the etch stop layer includes at least one layer fabricated from an insulative material that has high etching selectivity to an insulative material bounding the vias in the hybrid bonding layer.

Example 4. The IC die of Example 1, wherein the etch stop layer is in direct contact with a portion of the contact pad.

Example 5. The IC die of Example 4, wherein the etch stop layer is spaced from the top metal layer by a BEOL dielectric layer.

Example 6. The IC die of Example 1, wherein an area of the second opening formed in the etch stop layer is larger than an area of the first opening formed in the etch stop layer.

Example 7. The IC die of Example 1, wherein the etch stop layer has a thickness of between about 0.5 μm to about 20.0 μm.

Example 8. An integrated circuit (IC) device including: a first IC die having a first hybrid bonding layer disposed on a first etch stop layer of the first IC die, the first hybrid bonding layer including: a first metal filled via contacting a top metal layer of the first IC die though a first opening formed in the first etch stop layer; and a second metal filled via contacting a contact pad of the first IC die though a second opening formed in the first etch stop layer, the contact pad coupled to first metal layer by a contact pad via; and a second IC die stacked on the first IC die, the second IC die having a second hybrid bonding layer hybrid bonded to the first hybrid bonding layer.

Example 9. The IC device of Example 8, wherein the first etch stop layer includes at least one layer fabricated from a material selected from the group consisting of SiNₓ, SiCyNₓ, SiO_{y}Nₓ, and TiOₓ, where X and Y are positive numbers.

Example 10. The IC device of Example 8, wherein the first etch stop layer includes at least one layer fabricated from an insulative material that has high etching selectivity to an insulative material bounding the vias in the first hybrid bonding layer.

Example 11. The IC device of Example 8, wherein the first etch stop layer is in direct contact with a portion of the contact pad.

Example 12. The IC device of Example 8, wherein the top metal layer is further from the second IC die than the contact pad.

Example 13. The IC device of Example 8, wherein an area of the second opening formed in the first etch stop layer is larger than an area of the first opening formed in the first etch stop layer.

Example 14. The IC device of Example 8, wherein the first etch stop layer has a thickness of between about 0.5 μm to about 20.0 μm.

Example 15. The IC device of Example 8, wherein at least one or both of the first and second IC dies are memory dies.

Example 16. The IC device of Example 8, wherein at least one or both of the first and second IC dies are processor dies.

Example 17. A method for forming an integrated circuity die, the method including: depositing an etch stop layer over a contact pad exposed on an IC die, the contact pad coupled by a via to a first metal layer of the IC die; forming a first opening in the etch stop layer; depositing an insulative material over the etch stop layer; forming a first via through the insulative material, the first via stopping on the etch stop layer; forming a second via through the insulative material and through the first opening of the etch stop layer, the second via stopping on the first metal layer; forming a second opening in the etch stop layer that exposes a portion of the contact pad; and filling the first and second vias with conductive material.

Example 18. The method of Example 17, wherein forming the first via includes: etching the insulative material selectively to the etch stop layer.

Example 19. The method of Example 17, wherein depositing the etch stop layer includes: depositing at least one layer of a material selected from the group consisting of SiNₓ, SiCyNₓ, SiO_{y}Nₓ, and TiOₓ, where X and Y are positive numbers, to a thickness of between about 0.5 μm to about 20.0 μm.

Example 20. The method of Example 17 further including: depositing a hybrid bonding material disposed over the insulative material; forming openings in the hybrid bonding material that exposes the conductive material filling the first and second vias; and forming copper hybrid bonding pays on the conductive material filling the first and second vias disposed in the openings formed in the hybrid bonding material.

Example 21. A method for stacking integrated circuity (IC) dies, the method including: forming non-metal to non-metal bonds between a first hybrid bonding layer of a first IC die and a second hybrid bonding layer of a second IC die; and forming metal-to-metal bonds between hybrid bond pads of the first and second hybrid bonding layers of the first and second IC dies, a first one of the hybrid bond pads of the first hybrid bonding layer coupled by a first metal filled via of the first hybrid bonding layer to a top metal layer of the first IC die though a first opening formed in an first etch stop layer, and a second one of the hybrid bond pads of the first hybrid bonding layer coupled by a second metal filled via of the first hybrid bonding layer to contact pad disposed between top metal layer and the first etch stop layer through a first opening formed in the first etch stop layer.

Thus, integrated circuit (IC) dies and electronic devices including the same have been disclosed that include flexible routing arrangements enabled by the presence of an etch stop layer disposed between the hybrid bonding layers and the contact pads of the IC die. The etch stop layer enables vias to be fabricated that terminate at different metal layers of the IC die. The ability to form vias that terminate at conductive pads formed in different metal layers of the IC die enables routing congestion to be alleviated, enabling greater architectural and design flexibility, along with greater routing density.

What is claimed is:

1. An integrated circuit (IC) die comprising:
a substrate;
a front end of the line (FEOL) region disposed on the substrate, the FEOL region including functional circuitry;
a back end of the line (BEOL) region having a first side disposed on the FEOL region and a second side facing away from the FEOL region, the BEOL region including interconnect circuitry coupled to the functional circuitry, the interconnect circuitry comprising a top metal layer disposed adjacent to the second side of the BEOL region and a contact pad coupled to the top metal layer by a contact pad via;
an etch stop layer disposed on the second side of the BEOL region; and
a hybrid bonding layer disposed on the etch stop layer, the hybrid bonding layer comprising:
a first metal filled via contacting the top metal layer though a first opening formed in the etch stop layer; and
a second metal filled via contacting the contact pad though a second opening formed in the etch stop layer.

2. The IC die of claim 1, wherein the BEOL region includes at least one layer fabricated from a material selected from the group consisting of SiNₓ, SiCyNₓ, SiO_{y}Nₓ, and TiOₓ, where X and Y are positive numbers.

3. The IC die of claim 1, wherein the etch stop layer includes at least one layer fabricated from an insulative material that has high etching selectivity to an insulative material bounding the vias in the hybrid bonding layer.

4. The IC die of claim 1, wherein the etch stop layer is in direct contact with a portion of the contact pad.

5. The IC die of claim 4, wherein the etch stop layer is spaced from the top metal layer by a BEOL dielectric layer.

6. The IC die of claim 1, wherein an area of the second opening formed in the etch stop layer is larger than an area of the first opening formed in the etch stop layer.

7. The IC die of claim 1, wherein the etch stop layer has a thickness of between about 0.5 μm to about 20.0 μm.

8. An integrated circuit (IC) device comprising:
a first IC die having a first hybrid bonding layer disposed on a first etch stop layer of the first IC die, the first hybrid bonding layer comprising:
a first metal filled via contacting a top metal layer of the first IC die though a first opening formed in the first etch stop layer; and
a second metal filled via contacting a contact pad of the first IC die though a second opening formed in the first etch stop layer, the contact pad coupled to first metal layer by a contact pad via; and
a second IC die stacked on the first IC die, the second IC die having a second hybrid bonding layer hybrid bonded to the first hybrid bonding layer.

9. The IC device of claim 8, wherein the first etch stop layer includes at least one layer fabricated from a material selected from the group consisting of SiNₓ, SiCyNₓ, SiO_{y}Nₓ, and TiOₓ, where X and Y are positive numbers.

10. The IC device of claim 8, wherein the first etch stop layer includes at least one layer fabricated from an insulative material that has high etching selectivity to an insulative material bounding the vias in the first hybrid bonding layer.

11. The IC device of claim 8, wherein the first etch stop layer is in direct contact with a portion of the contact pad.

12. The IC device of claim 8, wherein the top metal layer is further from the second IC die than the contact pad.

13. The IC device of claim 8, wherein an area of the second opening formed in the first etch stop layer is larger than an area of the first opening formed in the first etch stop layer.

14. The IC device of claim 8, wherein the first etch stop layer has a thickness of between about 0.5 μm to about 20.0 μm.

15. The IC device of claim 8, wherein at least one or both of the first and second IC dies are memory dies.

16. The IC device of claim 8, wherein at least one or both of the first and second IC dies are processor dies.

17. A method for forming an integrated circuity die, the method comprising:
depositing an etch stop layer over a contact pad exposed on an IC die, the contact pad coupled by a via to a first metal layer of the IC die;
forming a first opening in the etch stop layer;
depositing an insulative material over the etch stop layer;
forming a first via through the insulative material, the first via stopping on the etch stop layer;
forming a second via through the insulative material and through the first opening of the etch stop layer, the second via stopping on the first metal layer;
forming a second opening in the etch stop layer that exposes a portion of the contact pad; and
filling the first and second vias with conductive material.

18. The method of claim 17, wherein forming the first via comprises:
etching the insulative material selectively to the etch stop layer.

19. The method of claim 17, wherein depositing the etch stop layer comprises:
depositing at least one layer of a material selected from the group consisting of SiNₓ, SiCyNₓ, SiO_{y}Nₓ, and TiOₓ, where X and Y are positive numbers, to a thickness of between about 0.5 μm to about 20.0 μm.

20. The method of claim 17 further comprising:
depositing a hybrid bonding material disposed over the insulative material;
forming openings in the hybrid bonding material that exposes the conductive material filling the first and second vias; and
forming copper hybrid bonding pays on the conductive material filling the first and second vias disposed in the openings formed in the hybrid bonding material.
